(19) United States
(12) Patent Application Publication
(10) Pub. No.: US 2026/0212940 A1
(43) Pub. Date: Jul. 23, 2026

(54) DRIVER AND TERMINATION (ZQ) CALIBRATION CIRCUITRY

(71) Applicant: Micron Technology, Inc., Boise, ID (US)

(72) Inventors: Timothy M. Hollis, Meridian, ID (US); Jennifer E. Taylor, Boise, ID (US); Eric J. Stave, Meridian, ID (US); Chulkyu Lee, Meridian, ID (US); Chris Gregory Holub, Bath, PA (US)

(21) Appl. No.: 19/412,017

(22) Filed: Dec. 8, 2025

Related U.S. Application Data
(60) Provisional application No. 63/747,182, filed on Jan. 20, 2025.

(51) Int. Cl. G11C 29/12; G11C 29/02; G11C 29/14

(52) U.S. Cl. CPC G11C 29/12005; G11C 29/028; G11C 29/14

(57) ABSTRACT

Systems and methods include a memory device that includes an internal voltage generator configured to receive a voltage level setting. The internal voltage generator also is configured to generate an internal voltage based at least in part on the voltage level setting. The memory device also includes ZQ calibration circuitry that is configured to receive the internal voltage from the internal voltage generator and to perform ZQ calibration using the received internal voltage.

### CROSS-REFERENCE TO RELATED APPLICATIONS

This application claims priority to U.S. Provisional Application No. 63/747,182, filed January 20, 2025, which is incorporated by reference herein in its entirety.

### BACKGROUND

### FIELD OF THE INVENTION

Embodiments of the present disclosure relate generally to the field of semiconductor memory devices. More specifically, embodiments of the present disclosure relate to a driver and termination calibration circuitry in a dynamic random access memory (DRAM) device.

### DESCRIPTION OF THE RELATED ART

The operational rate of memory devices, including the data rate of a memory device, has been increasing over time. As a side effect of the increase in speed of a memory device, data errors may become more problematic. For example, memory devices may be susceptible to voltage and/or temperature variations that may negatively impact signal integrity and/or data reliability especially in high-speed memory systems. To compensate for such variations in voltage and/or temperature variations, memory devices may utilize driver and termination (ZQ) calibration to fine tune a memory’s internal impedance to maintain optimal signal quality across different operating conditions. Such calibration may use a dedicated ZQ pin connected to a precision external resistor that acts as a reference point to calibrate the internal drive strength and termination resistance of the memory device. By calibrating such internal drive strength and termination, ZQ calibration circuitry minimizes signal reflections and ensures reliable data transmission even at high frequencies. This calibration increases memory bandwidth and performance and reduces errors. However, these calibration circuitries may rely on external power supplies (e.g., from a host and/or power management integrated circuit (PMIC)) that require receiving a new voltage level from the external power supply requiring more of the host device and/or the PMIC and then requiring a recalibration of ZQ.

### BRIEF DESCRIPTION OF THE DRAWINGS

Various aspects of this disclosure may better be understood upon reading the following detailed description and upon reference to the drawings in which:

FIG. 1 is a simplified block diagram illustrating certain features of a memory device that includes ZQ calibration circuitry, according to an embodiment of the present disclosure;

FIG. 2 illustrates a block diagram of an embodiment of the ZQ calibration circuitry using an external voltage, according to an embodiment of the present disclosure;

FIG. 3 illustrates a block diagram of an embodiment of internal voltage generator used to generate one or more internal voltages, according to an embodiment of the present disclosure;

FIG. 4 illustrates a block diagram of an embodiment of the ZQ calibration circuitry using an internal voltage, according to an embodiment of the present disclosure;

FIG. 5 is a block diagram illustrating performing a ZQ calibration using the internal voltage of FIG. 4, according to an embodiment of the present disclosure;

FIG. 6 is a block diagram illustrating performing a ZQ calibration using the internal voltage of FIG. 4, according to an embodiment of the present disclosure; and

FIG. 7 is a flow diagram for populating a LUT with calibration values for multiple modes, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As is discussed below, by using an internal voltage that has a voltage level controllable by the memory device, the memory device may adjust ZQ calibration for different VDDQ levels for different modes of operation and may limit host and/or PMIC interactions during a mode change process. This internal voltage may be adjusted to reflect anticipated changes in the externally supplied VDDQ voltage that may coincide with a variety of modes of operation. Furthermore, this adjustment may be made without interaction and/or demands placed on the host device and/or the PMIC.

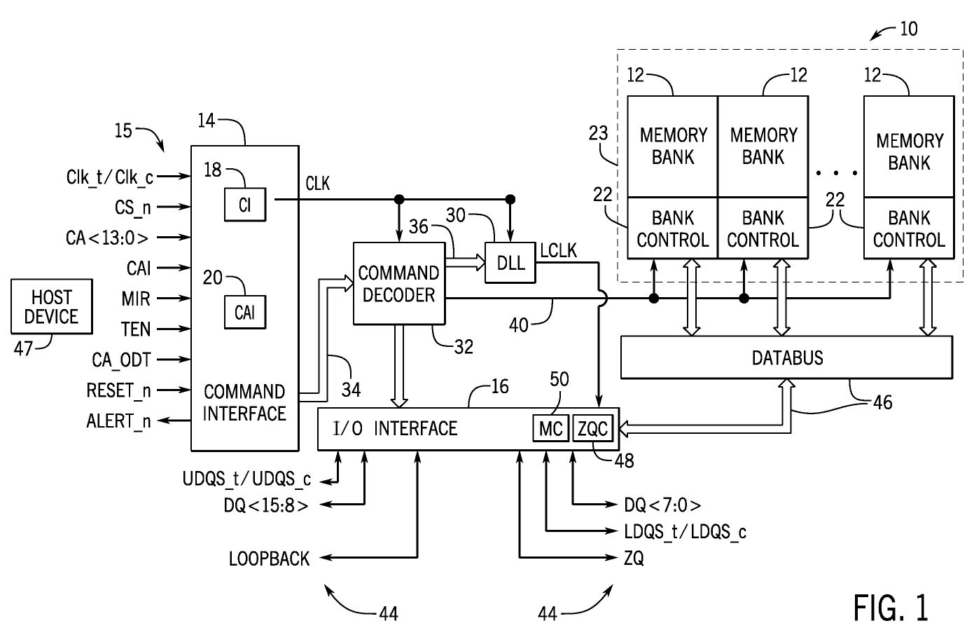

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type four (DDR4 SDRAM), a double data rate type five synchronous dynamic random-access memory (DDR5 SDRAM) device, a low-power double data rate type four (LPDDR4 SDRAM), a low-power double data rate type five (LPDDR5 SDRAM), and/or another new type, such as double data rate type six (DDR6 SDRAM). Various features of DDR SDRAM devices allow for reduced power consumption, more bandwidth and more storage capacity compared to prior generations of DDR SDRAM.

The memory device 10 may include a number of memory banks 12. The memory banks 12 may be DDR6 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12, arranged into 8 bank groups, each bank group including 4 memory banks, for instance. Various other configurations, organization, and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the internal clock generator 30 over the bus 36 to coordinate generation of the phase controlled internal clock signal LCLK. The phase controlled internal clock signal LCLK may be used to clock data through the I/O interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12. Collectively, the memory banks 12 and the bank control blocks 22 may be referred to as a memory array 23.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over a data bus 46 that includes multiple bi-directional data connections. Data I/O signals, generally referred to as DQ signals, are generally transmitted and received in one or more bi-directional data connections. For certain memory devices, such as a DDR5 SDRAM memory device, the I/O signals may be divided into upper and lower bytes. For instance, for an x16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance. In some embodiments as discussed below, the DQS may be internally generated from a clock received at the memory device 10 from the host device 47. In some such embodiments the DQS pins may be omitted from the memory device 10.

An impedance (ZQ) calibration signal may also be provided to the memory device 10 through the I/O interface 16. The ZQ calibration signal may be provided to a reference pin and used to tune output drivers and ODT values by adjusting pull-up and pull-down resistances of the memory device 10 across changes in process, voltage, and temperature (PVT) values. Because PVT characteristics may impact the ZQ resistor values, the ZQ calibration signal may be provided to the ZQ reference pin to be used to adjust the resistance to calibrate the input and output impedances to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory system 10. Accordingly, it should be understood that the block diagram of FIG. 1 is only provided to highlight certain functional features of the memory device 10 to aid in the subsequent detailed description.

In some embodiments, the memory device 10 may be coupled to a host device 47. The host device 47 may include a processor, such as a central processing unit (CPU), a graphics processing unit (GPU), another microprocessor, a programmable logic device, and/or any other suitable processor that controls processing of system functions and requests. Further, any host device/processor may include multiple processing units.

The I/O interface 16 may also include ZQ calibration circuitry (ZQC) 48 that performs ZQ calibration during startup and/or periodically during operation of the memory device 10. Specifically, as discussed below, the ZQC 48 calibrates an internal termination and driving level for operation of the memory device 10, which generally includes identifying the internal circuit configuration that best matches the target behavior based on the relationship between the internal circuitry and the external RZQ resistor..

Furthermore, the I/O interface 16 and/or other parts of the memory device 10 may include monitoring circuitry (MC) 50 that may monitor operations of the memory device to determine an operating mode. For instance, the MC 50 may determine a mode of operation for the memory device 10 by monitoring a mode register that indicates an operating mode (e.g., higher power or lower power mode) of the memory device 10. The ZQC 48 may use such modes of operation to properly set ZQ values. Additionally or alternatively, the ZQC 48 may determine such modes of operation indirectly by measuring one or more voltages, such as a reference voltage and/or an externally supplied external voltage.

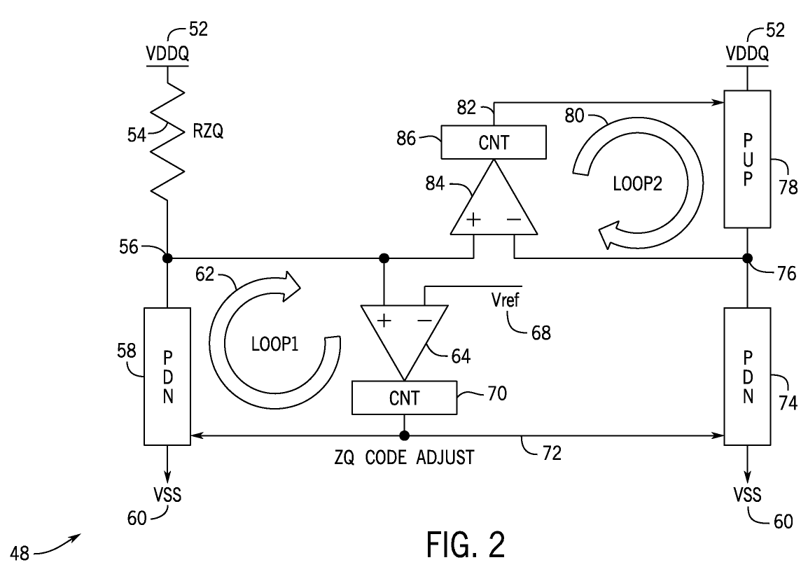

FIG. 2 is a block diagram of an embodiment of the ZQC 48 using an externally supplied voltage. For example, the ZQC 48 may be similar to ZQCs used in LPDDR4 SDRAM devices, LPDDR5 SDRAM devices, or LPDDR type 6 (LPDDR6 SDRAM devices). As such, the ZQC 48 includes a connection to VDDQ 52. In some embodiments, VDDQ 52 may be supplied to the memory device 10 from outside of the memory die 10. For instance, the VDDQ 52 may be supplied by PMIC of the host device 47 and/or controlled by the host device 47. A precision external resistor (RZQ) 54 may be tuned to a specific impedance (e.g., 240 Ω) and connected to VDDQ 52. For instance, this VDDQ 52 may be connected to the memory device 10 via the ZQ pin and via the RZQ 54. This RZQ 54 acts as a reference to calibrate the termination impedance and drive strength of the memory device 10. By performing ZQ calibration during startup and/or at different intervals, the memory device 10 may compensate for voltage and/or temperature variations.

The RZQ 54 may be coupled to a node 56 that is then terminated to VSS 60 through a pull-down driver (PDN) 58. The PDN 58 may include multiple legs that are tuned to a specific impedance (e.g., 240 Ω) using a series resistor coupled to a transistor (e.g., a pull-down NMOS transistor) that act as legs of a voltage divider. The PDN 58 may match a driver architecture of the memory device 10. For instance, the driver architecture may be a NMOS-over-NMOS low-voltage swing-terminated logic (LVSTL)-based interface or another suitable driver architecture.

The ZQC 48 further includes a loop 62 that is used to match the impedance of the PDN 58 to the RZQ 54 at least to some proportion. To achieve this match, the ZQC 48 includes a comparator 64, such as an op-amp, that has its non-inverting input coupled to the node 56 and has its inverting input coupled to a reference voltage (Vref) 68. The Vref 68 may be received from outside of the memory device 10 and/or may be generated within the memory device 10. For instance, the Vref 68 may be generated using a bandgap generation circuitry and/or any other circuitry. This Vref 68 may be proportional to the VDDQ 52, such as one-half, one-third, and the like. For instance, if Vref 68 is half of the voltage of VDDQ 52, the voltage of the node 56 is equal to the Vref 68 when the impedance of the RZQ 54 is equal to the impedance of the PDN 58.

An output of the comparator 64 is passed to a counter 70. When the output of the comparator 64 indicates that the inputs to the comparator 64 are different voltages, the counter 70 may increment a ZQ code adjust signal 72 that adjusts the impedance in the PDN 58. In other words, the counter 70 steps through the calibration until the trip point of the calibration where the voltage of the node 56 is equal to the Vref 68. For instance, the trip point may occur when the impedance of the RZQ 54 is equal to the impedance of the PDN 58 when the Vref 68 is set to half of the VDDQ 52. After this tipping point, the counter 70 stops counting and the ZQ code adjust signal 72 is set with the impedance of the PDN 58 set to a target value (e.g., equal to the impedance of the RZQ 54). Thus, the loop 62 is completed once the PDN 58 impedance is set.

While incrementing the ZQ code adjust signal 72, the ZQC 48 may submit the ZQ code adjust signal 72 to the PDN 58 along with another PDN 74 that is similarly terminated to VSS 60. The PDN 74 may be constructed similarly to the PDN 58 such that the two may be driven to the same impedance with the same input. This causes the impedance of the PDN 74 to be equal to or at least proportional to the impedance of the PDN 58. In embodiments where the Vref 68 is half of the VDDQ 52, the impedance of the RZQ 54, the PDN 58, and the PDN 74 are all the same once the calibration in the loop 62 has completed. Each of the PDN 58 and the PDN 74 pulls a respective node, the node 56 and the node 76, down toward VSS.

After setting the impedance in the PDN 74 using the loop 62, the ZQC 49 uses a loop 80 to set the impedance of a pull-up driver (PUP) 78. The PUP 78 may be similar to the PDNs 58 and/or 74 except that PUP 78 pulls the node 76 up toward VDDQ 52 rather than pulling the nodes 56 or 76 down toward VSS 60. The loop 80 is like the loop 62 except that it uses a different code adjust signal 82 to adjust operation of the PUP 78. The code adjust signal 82 is like the ZQ code adjust signal 72 except that the final result of the code adjust signal 82 is to set the impedance of the PUP 78 proportional to (e.g., the same as) that of the RZQ 54. This proportionality of the impedance of the PUP 78 to the impedance of the RZQ 54 may be independent from the proportion of the impedances of the PDN 58 and the PDN 74 to the RZQ 54. In other words, in some embodiments, the impedance of the PUP 78 may be equal to the impedance of the RZQ 54 even if the impedances of the PDNs 58 and 74 are not equal to the impedance of the RZQ 54. In other words, the impedance of the PUP 78 may be the same as the impedance of the RZQ 54 even if the Vref 68 is not half of VDDQ 52.

To set the impedance of the PUP 78 using the loop 80, the ZQC 48 includes a comparator 84 that is coupled to the node 56 and to the node 76. For instance, the non-inverting input of the comparator 84 may be coupled to the node 56 while the inverting input of the comparator 84 may be coupled to the node 76. Like the comparator 64, the comparator 84 may walk through different values in a counter 86 until a tipping point. The tipping point when the code adjust signal 82 is set is when the voltage of the node 56 is equal to the node 76. This point occurs when the impedance of the PUP 78 is equal to the impedance of the RZQ 54 because the impedances of the PDNs 58 and 74 are the same. This is true since each channel is coupled between VDDQ 52 and VSS 60 and the impedances of the PUP 78 and RZQ 54 match while the impedances of the PDN 58 and the PDN 74 match. In this state, the ZQ calibration has been completed, and memory operations may be performed using the ZQ calibrations.

In some embodiments, VDDQ may be expected to vary thereby requiring system interaction via the host device 47 and/or a PMIC to make adjustment. Furthermore, in some embodiments, such as DDR5, common VDD and VDDQ levels result in no intentional VDDQ adjustment between modes of operation. To simplify multiple VDDQ levels for varying modes of operation and/or reduce requirements on the host/PMIC during VDDQ changes, an internal voltage (VDDQInt) may be used for ZQ calibration.

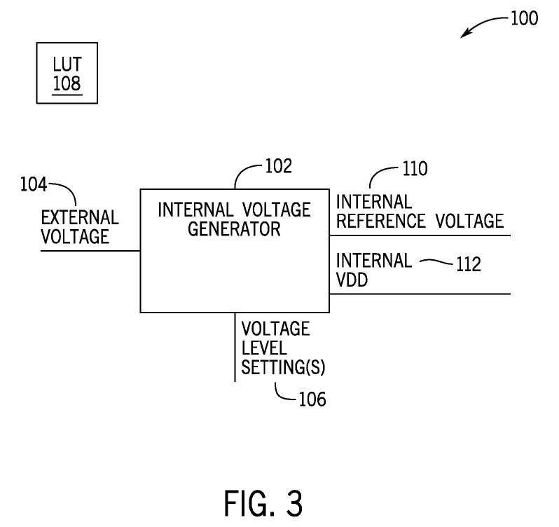

FIG. 3 is a block diagram of an internal voltage generator 102 that receives an external voltage 104. This external voltage 104 may be VDDQ 52. However, since the memory device 10 may use different VDDQ levels for different modes of operation, it may internally generate these different levels based on voltage level setting(s) 106. These voltage level setting(s) 106 may be an explicit indication of a mode of operation via a mode register of the memory device 10 and/or may be based on measurements. For instance, the voltage level setting(s) may be based on a voltage level of the external voltage 104 and/or based on a reference voltage level. The internal voltage generator 102 may use a lookup table (LUT) 108 that stores values for an internal reference voltage 110 and/or an internal VDD 112. The LUT 108 may be a register located at any location within the memory device 10, such as in the command interface 14, the I/O interface 16, the command decoder 32, and/or any other suitable location within the memory device 10. The voltage levels for the internal reference voltage 110 and/or the internal VDD 112 are generated according to the voltage level setting(s) 106. In some embodiments, since the voltage levels of internal reference voltage 110 and the internal VDD 112 are related for use in ZQ calibration, the LUT 108 may store paired values for the internal reference voltage 110 and the internal VDD 112.

The internal reference voltage 110 may be a reference voltage that is internally generated in the internal voltage generator 102 of the memory device based on the external voltage 104 (e.g., VDDQ 52). For instance, the internal voltage generator 102 may include a bandgap reference voltage generator that generates a stable, temperature-independent voltage close to the bandgap energy of silicon (e.g., 1.2 V). Additionally or alternatively, the internal voltage generator 102 may include one or more level shifters to shift the external voltage and any generated voltages (e.g., bandgap voltage) to a desired level based on the voltage level setting(s) 106 and the LUT 108. Similarly, the internal VDD 112 may be a VDD voltage that is internally generated in the internal voltage generator 102 based on the voltage level setting(s) 106 and the LUT 108. The ratio of the internal reference voltage 110 and the internal VDD 112 may be set (e.g., 1 to 2, etc.). Alternatively, this ratio may change based on the mode of operation of the memory device 10.

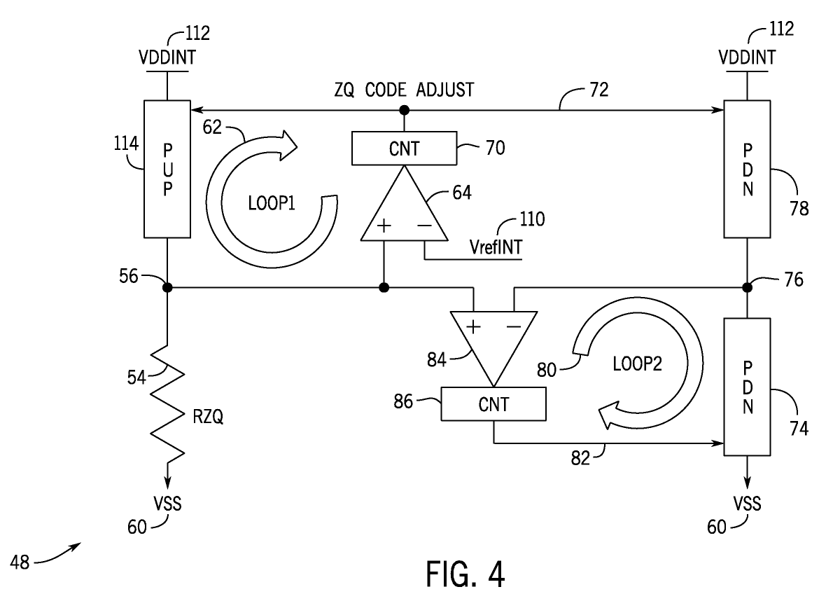

FIG. 4 is a block diagram of an embodiment of the ZQC 48 that uses internal voltages. The embodiment of the ZQC 48 in FIG. 2 may function similar to the embodiment of the ZQC 48 in FIG. 2 except that the internal VDD (VDDInt) 112 is in place of the externally received VDDQ 52 and that FIG. 4 uses the internal reference voltage (VrefInt) 110. In some embodiments, the VrefInt 110 and the Vref 68 may be the same for at least some situations/settings (e.g., at least some of the voltage level setting(s) 106). Additionally or alternatively, the VrefInt 110 and the Vref 68 may be different for at least some situations/settings (e.g., at least some of the voltage level setting(s) 106).

By internally generating the VDDInt 112, the memory device 10 may change the VDDInt 112 internally based on a mode of operation. For instance, the VDDInt 112 may have a first level (e.g., 0.6 V) for a high-speed, low-voltage interface operation in a first mode and may have a second level (e.g., 0.4 V) for low-speed, low-power open termination signaling in a second mode. Moreover, the level of the VDDInt 112 may be paired with an appropriate VrefInt 110 value that is stored in the LUT 108.

Also, the ZQC 48 of FIG. 4 differs from the ZQC 48 of FIG. 2 in that the RZQ 54 is connected to VSS 60 rather than VDD 52 (or VDDInt 112), and the PDN 58 is replaced by a PUP 114 that matches the PUP 78. This change of the location of the RZQ 54 causes some changes to the operation of the ZQC 48 such as using the loop 62 and the comparator 64 to adjust operation of the PUPs 78 and 114 in a first loop and subsequently adjusting operation of the PDN 74 in the loop 80. The principles discussed herein may be applicable using different implementations of ZQC 48 whether the RZQ 54 is terminated to VSS 60 or terminated to VDDInt 112.

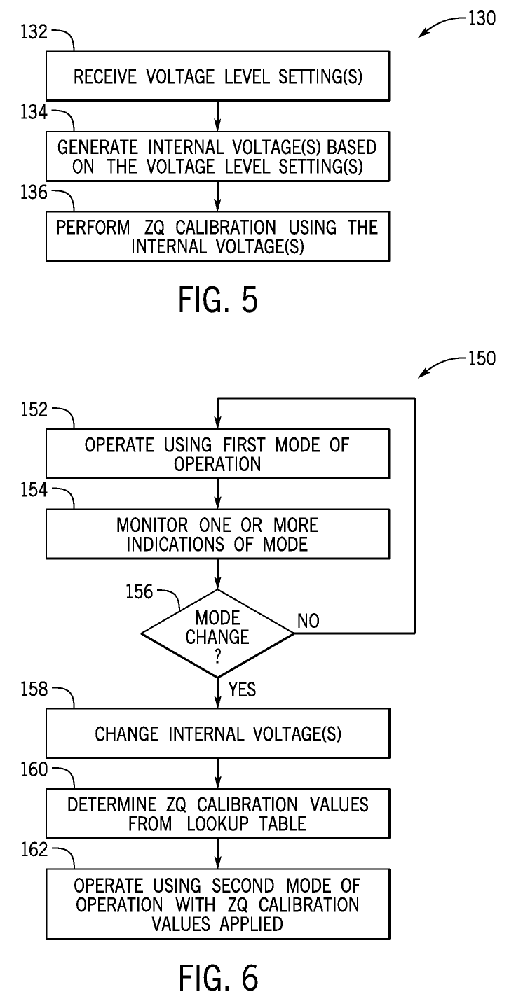

FIG. 5 is a flow diagram of a process 130 for using the internal voltages (VDDInt 112) in ZQ calibration of the memory device. At least some portion of the memory device 10 (e.g., the internal voltage generator 102) receives voltage level setting(s) (block 132). For instance, the voltage level setting(s) 106 may be actual settings such as the voltage level setting(s) 106 received via a mode register from the host device 47 that indicates a mode of operation for the memory device 10 with an explicit setting.

Additionally or alternatively to receiving an explicit indicator of a mode of operation, monitoring circuitry (MC) 50 may monitor one or more parameter of the memory device 10 to determine the mode of operation. For instance, the MC 50 may monitor one or move voltages, such as the Vref 68, the VDDQ 52, and/or another external voltage, to determine a mode of operation. In such embodiments, the voltage level setting(s) may be determined from these monitored voltages.

In monitoring the Vref 68, the MC 50 may digitally monitor Vref programming from the host device 47 to identify shifts between one mode (e.g., high-speed with a higher voltage (e.g., 0.6 V) and a second mode (e.g., lower-speed with a lower voltage (e.g., 0.4 V). Additionally or alternatively, the MC 50 may monitor the actual level of the Vref 68 in analog values to monitor for shifts between modes. Since these shifts, either measured directly using analog monitoring or indirectly using digital monitoring of programming, may have a relatively large expected value (e.g., 200 mV or more), these shifts may be filtered to imply a change of mode of operation only when the Vref has a change above a threshold (e.g., 100 mV). In other words, a change to the Vref greater the threshold may be deemed a voltage level setting causing the ZQC 48 to change an internal voltage, such as the VDDInt 112 and/or the VrefInt 110. Alternatively or additionally, the MC 50 may monitor the VDDQ supply for shifts greater than a VDDQ threshold (e.g., around 200 mV, > 150 mV, etc.) similar to the discussion for monitoring the Vref using a filter. These filters may be sufficient to distinguish actual voltage level changes as voltage level settings associated with a change in mode of operation rather than just noise on the supplied voltages.

To further distinguish voltage changes from noise and/or other operation variations unattached to a change in mode of operation, additional filtration may be used in determining whether to change the internal voltages based on the received values. For instance, during characterization conditions, such as RMT, monitoring may be at least partially disabled. For instance, during RMT, Vref might be swept to measure eye aperture or to locate eye positions. To avoid unintentional updates to the internal voltages based on such sweeps, the MC 50 may be at least disabled and/or ignored during such characterization conditions.

Returning to FIG. 5, based on the voltage level setting(s), the internal voltage generator 102 generates internal voltage(s) to respective voltage levels (block 134). As previously discussed, the internal voltages may include the VrefInt 110 and the VDDInt 112. As previously discussed, these levels may be generated by setting their levels using the LUT 108 to determine the levels from a set mode of operation or based on a change of the Vref 68, the VDDQ 52, and/or any other externally supplied voltage. Generating these internal voltages also includes supplying them to the ZQC 48. Furthermore, since the internal voltages used for ZQ calibration are generated internally, changing the internal voltages and recalibrating may be performed without input and/or involvement from the host device 47 and/or other circuity (e.g., PMIC) of the host.

The ZQC 48 then uses the internal voltage(s) to perform ZQ calibration (block 136). For instance, the ZQC 48 may determine ZQ the ZQ code adjust signal 72 and the code adjust signal 82 using the techniques discussed in relation to FIG. 4. The memory device 10 then uses the ZQ calibration to adjust operation of the memory device 10. For instance, the memory device 10 may use the ZQ code adjust signal 72 and/or the code adjust signal 82 to alter operation of the memory device 10 to set termination and/or drive strengths to stabilize operation of the memory device.

FIG. 6 is a flow diagram of a process 150 for using internal voltages (e.g., the VDDInt 112) in ZQ calibration of the memory device 10 at different levels for different modes of operation. The memory device 10 performs memory operations in a first mode of operation (block 152). The first mode of operation may be a default mode using a first voltage level (e.g., 0.4 or 0.6 V). For example, the first voltage level may be relatively high (e.g., 0.6 V) compared to voltage levels (e.g., 0.4 V) of other modes of operation in exchange for higher speed.

Monitoring circuitry (MC 50) of the memory device 10 monitors for one or more indications of mode (block 154). The indications of mode may include an explicit setting in the voltage level setting(s) 106 received via a mode register from the host device 47 that indicates a mode of operation for the memory device 10 with an explicit setting. Additionally or alternatively to receiving an explicit indicator of a mode of operation via a mode register, the MC 50 may monitor one or more parameter of the memory device 10 to determine the mode of operation. For instance, the MC 50 may monitor one or move voltages, such as the Vref 68, the VDDQ 52, and/or another external voltage, to determine a mode of operation. In such embodiments, the voltage level setting(s) may be determined from these monitored voltages.

In monitoring the Vref 68, the MC 50 may digitally monitor Vref programming from the host device 47 to identify shifts between one mode (e.g., high-speed with a higher voltage (e.g., 0.6 V) and a second mode (e.g., lower-speed with a lower voltage (e.g., 0.4 V). Additionally or alternatively, the MC 50 may monitor the actual level of the Vref 68 in analog values to monitor for shifts between modes.

The MC 50 may monitor these one or more indications to determine whether there is an indicated mode change (block 156). For instance, the MC 50 may determine that a mode register indicating a mode of operation has changed. Additionally or alternatively, the MC 50 may monitor a shift in monitored voltages as an indication of a change in mode. Since these shifts may have a relatively large expected value (e.g., 200 mV or more), these shifts may be filtered to imply a change of mode of operation only when the monitored voltage, such as the Vref 68 or the VDDQ, has a change above a threshold (e.g., 100 mV, 150 mV, 200 mV, etc.). In other words, a change to one or more of the monitored voltages greater a respective threshold may be deemed an indication that the mode has changed. The thresholds may be the same or different for each monitored voltage. Using the thresholds enables the MC 50 to distinguish actual voltage level changes associated with a change in mode of operation from noise and/or other transient changes on the supplied voltages. To further distinguish voltage changes corresponding to mode changes from noise and/or other operation variations unattached to a change in mode of operation, additional filtration may be used in determining whether to change the internal voltages based on the received values. For instance, during characterization conditions, such as RMT, monitoring may be at least partially disabled. For instance, during RMT, Vref might be swept to measure eye aperture or to locate eye positions. To avoid unintentional updates to the internal voltages based on such sweeps, the MC 50 may be at least disabled and/or ignored during such characterization conditions.

If the mode has not changed, the memory device 10 continues operating using the first mode of operation and monitoring the one or more indications of mode. However, if the mode has changed, the internal voltage generator 102 changes the voltage level of the one or more internal voltages (block 158). For instance, the internal voltage generator 102 may use the LUT 108 along with the indications of mode change (e.g., mode register values, voltage level of the Vref 68, voltage level of the VDDQ 52, etc.) to determine corresponding voltage levels of the internal voltages, the internal reference voltage (VrefInt) 110 and/or the VDDInt 112. The internal voltage generator 102 then generates and transmits these newly generated voltage levels to the ZQC 48.

The memory device 10 then uses the LUT 108 to determine ZQ calibration values (block 162). For instance, during initialization of the memory device 10 during startup, the ZQC 48 may use the techniques discussed in relation to FIG. 4 above during an initialization across multiple different voltages/modes, termination, and drive strengths during startup and storing such ZQ calibration values to the LUT 108. Additionally or alternatively, ZQ calibration may be performed using the ZQC 48 after selecting a voltage. Once the ZQ calibration values have been determined from the LUT 108 and/or recomputed, the memory device 10 uses the ZQ calibration value to perform memory operations in the second mode of operation with the ZQ calibration applied (block 162). For instance, the memory device 10 may use the ZQ code adjust signals 72 and the code adjust signals 82 to control termination and drive strength of the memory device 10 during memory operations.

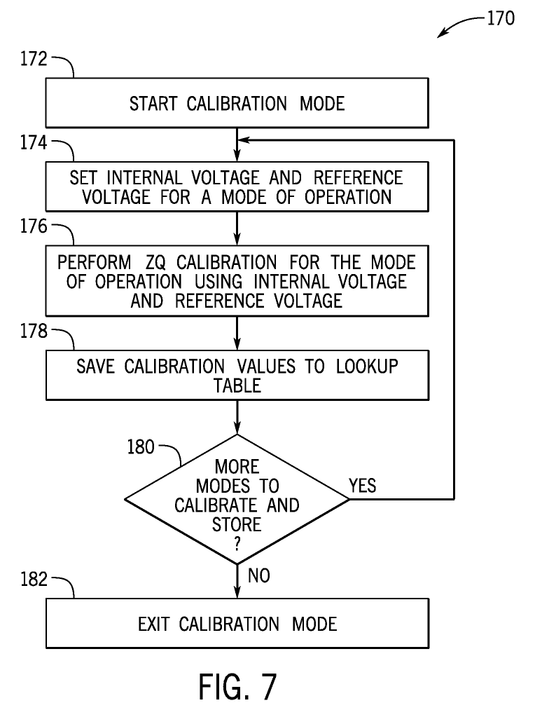

FIG. 7 is a flow diagram of a process 170 that is used to populate the LUT 108 for multiple modes operation. The process 170 begins with the memory device 10 entering a calibration mode (block 172). For instance, the memory device 10 may enter the calibration mode upon startup and/or based on an indication to enter calibration mode from a host device. Additionally or alternatively, the memory device 10 may enter the calibration mode autonomously. For example, during normal operation, internal telemetry (e.g., internal temperature or voltage sensing), a internal counter, and/or another mechanism in the memory device 10 may trigger the ZQC 48 to enter the calibration mode to add to and/or refress the initially determined calibration solution. In the calibration mode, the internal voltage generator 102 sets an internal voltage (e.g., VDDInt 112) and/or an internal reference voltage (e.g., VrefInt 110) (block 174). For instance, the internal voltage and/or internal reference voltage may correspond to a first mode being calibrated in the calibration mode. In subsequent modes being tested, one of the voltages may be the same between modes meaning that setting the voltage may include keeping the voltage to a previously set level for another mode while changing the other voltage. Once the voltages are set, the ZQC 48 performs calibration for the mode of operation using these values (block 176). As previously discussed, this calibration results in codes that set impedance values that control termination and/or drive strength. Once these values are determined, the values are stored to the lookup table (block 178).

If additional modes are to be tested (block 180), the process 170 returns to block 174 to obtain calibration values for the new mode. In some embodiments, the next mode to be calibrated for may be controlled by the memory device 10 and/or the host device 47. Once all modes to be calibrated for have been calibrated, the memory device 10 exits the calibration mode (block 182). At this point, the memory device 10 may begin the process 150 of FIG. 6.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A memory device, comprising:
an internal voltage generator configured to:
receive a voltage level setting; and
generate an internal voltage based at least in part on the voltage level setting; and
ZQ calibration circuitry configured to:
receive the internal voltage from the internal voltage generator; and
perform ZQ calibration using the received internal voltage.

2. The memory device of claim 1, wherein the internal voltage generator is configured to change a voltage level of the internal voltage based on a mode of operation for the memory device.

3. The memory device of claim 2, wherein the internal voltage generator is configured to change the voltage level of the internal voltage without interaction with a host for the memory device.

4. The memory device of claim 1, wherein the voltage level setting comprises a mode register setting that directly indicates a mode of operation for the memory device.

5. The memory device of claim 1, comprising monitoring circuitry configured to monitor an external voltage received at the memory device.

6. The memory device of claim 5, wherein the internal voltage comprises an internal supply voltage and an internal reference voltage.

7. The memory device of claim 6, wherein the internal supply voltage is greater than the internal reference voltage.

8. The memory device of claim 7, wherein the internal supply voltage is double the internal reference voltage.

9. The memory device of claim 6, wherein receiving the voltage level setting comprises receiving an indication that the external voltage has moved from a previous value by more than a threshold amount.

10. The memory device of claim 7, wherein the external voltage comprises an externally received supply voltage from a power management integrated circuit external to the memory device.

11. The memory device of claim 6, wherein receiving the voltage level setting comprises receiving a programming for a reference voltage from a host to the memory device.

12. A method, comprising:
operating a memory device using a first mode of operation;
monitoring, by monitoring circuitry, one or more indications of mode for the memory device;
determining that a mode of operation for the memory device is to change from the first mode of operation to a second mode of operation;
determining ZQ calibration values from a lookup table; and
operating the memory device using the second mode of operation with applied ZQ calibration values for the second mode of operation that is different than the first mode of operation.

13. The method of claim 12, wherein determining that the mode of operation has changed is performed using an internal voltage generator that generates the internal voltage or by the monitoring circuitry that controls the generation of the internal voltage.

14. The method of claim 12, wherein monitoring the one or more indications comprises monitoring a mode register that stores a value indicative of a mode of operation for the memory device.

15. The method of claim 12, wherein monitoring the one or more indications comprises monitoring an actual received supply voltage or an actual reference voltage of the memory device.

16. The method of claim 12, wherein monitoring the one or more indications comprises monitoring voltage programming for a reference voltage of the memory device from a power management integrated circuit external to the memory device.

17. The method of claim 12, wherein the internal voltage comprises an internal supply voltage through which a ZQ resistor of calibration circuitry is connected.

18. A method for operating a memory device comprising:
receiving, at an internal voltage generator of the memory device, a voltage level setting indicating a mode of operation for the memory device;
generating, in the internal voltage generator, internal voltages based on the indicated mode of operation; and
performing ZQ calibration in ZQ calibration circuitry of the memory device using the internal voltages.

19. The method of claim 18, wherein the voltage level setting comprises:
a mode register indicative of a mode of operation for the memory device; or
a voltage level setting based at least in part on monitoring of a received voltage or a received programming for a reference voltage of the memory device.

20. The method of claim 18, wherein the internal voltages comprise:
an internal supply voltage coupled to a first end of a ZQ resistor of the ZQ calibration circuitry; and
an internal reference voltage that is compared to a node at a second end of the ZQ resistor by a comparator that is coupled to the node and to the internal reference voltage.
